(19) United States
(12) Patent Application Publication
(10) Pub. No.: US 2023/0180576 A1
(43) Pub. Date: Jun. 8, 2023

(54) PHOTOELECTRIC SENSOR, METHOD OF MANUFACTURING THE SAME, AND DISPLAY PANEL

(71) Applicant: TCL CHINA STAR OPTOELECTRONICS TECHNOLOGY CO., LTD., Shenzhen (CN)

(72) Inventor: Guangshuo Cai, Shenzhen (CN)

(73) Assignee: TCL CHINA STAR OPTOELECTRONICS TECHNOLOGY CO., LTD., Shenzhen (CN)

(21) Appl. No.: 17/425,718

(22) PCT Filed: May 28, 2021
(86) PCT No.: PCT/CN2021/096967

§ 371 Date: Jul. 23, 2021

(30) Foreign Application Priority Data
Apr. 13, 2021 (CN) 202110394193.3

(51) Int. Cl. H10K 59/60; H10K 50/15; H10K 50/16; H10K 59/12; H10K 71/16; H10K 59/80

(52) U.S. Cl. CPC H10K 59/60; H10K 50/15; H10K 50/16; H10K 59/1201; H10K 71/16; H10K 59/8792; H10K 2102/102

(57) ABSTRACT

The embodiments of the present disclosure provide a photoelectric sensor and a method of manufacturing the same, and a display panel. The photoelectric sensor includes a transparent substrate, a hole transport layer, a light absorption layer, and an electron transport layer. Disposing the hole transport layer on one side close to the transparent substrate and shielding the hole transport layer by use of the light absorption layer and the electron transport layer avoid the dissolution of molybdenum oxide in the hole transport layer during a cleaning process and reduce the difficulty in manufacturing process of the photoelectric sensor.

### FIELD OF INVENTION

The present disclosure relates to the technical field of display, and particularly, to a photoelectric sensor, a method of manufacturing the same, and a display panel.

### BACKGROUND OF INVENTION

With the rapid development of information technology, the use of fingerprint, voice, face, hand, retina or iris as a personal identification system has become a safe and reliable biometric technology. From the perspective of costs, ease of use, and accuracy, fingerprint identification has become a leading method for identity verification, and has replaced conventional passwords and keys. Traditional optical fingerprint recognition sensors have problems, such as high costs, large sizes, and image distortion. Silicon chip-based sensors have gradually replaced traditional optical fingerprint identification sensors, due to their small sizes and low prices. However, silicon chip-based sensors are prone to electrostatic breakdown and susceptible to environmental conditions, which limit their further application.

### Technical Problems

Compared with silicon-based PN junction sensors, sensors with semiconductor heterostructures have the advantages of high photoelectric conversion efficiency, high reliability, and low costs. In addition, the use of transparent oxide MoOx having a high work function as a hole transport layer material may reduce the additional loss of light and enhance the hole transport effect of the sensor. A surface of the film layer will be cleaned before each process of manufacturing the sensor. Since the MoOx having the high work function is easily soluble in water, when cleaning the surface of the hole transport layer made of MoOx, the MoOx will be dissolved, resulting in the failure of subsequent processes.

In summary, the conventional sensors which use molybdenum oxide as the hole transport layer material have the problem of manufacturing difficulty. Therefore, it is necessary to provide a photoelectric sensor, a method of manufacturing the same, and a display panel.

### SUMMARY OF INVENTION

The embodiments of the present disclosure provide a photoelectric sensor, a method of manufacturing the same, and a display panel to solve the problem of manufacturing difficulty in the conventional sensors which use molybdenum oxide as the hole transport layer material.

The embodiments of the present disclosure provide a photoelectric sensor. The photoelectric sensor comprises:

a transparent substrate;

a hole transport layer disposed on the transparent substrate;

a light absorption layer disposed on one side of the hole transport layer away from the transparent substrate; and

an electron transport layer disposed on one side of the light absorption layer away from the hole transport layer;

wherein one side of the transparent substrate away from the hole transport layer is a light incident side of the photoelectric sensor, and a material of the hole transport layer is molybdenum oxide.

According to one embodiment of the present disclosure, a forbidden band width of the molybdenum oxide is greater than or equal to 2.8 eV and less than or equal to 3.6 eV, and a work function of the molybdenum oxide is greater than or equal to 5.2 eV and less than or equal to 6.8 eV.

According to one embodiment of the present disclosure, the light absorption layer is an intrinsic semiconductor. The electron transport layer is an electronic semiconductor. The hole transport layer, the light absorption layer, and the electron transport layer form a semiconductor heterostructure.

According to one embodiment of the present disclosure, materials of the light absorption layer and the electron transport layer comprise any one of amorphous silicon, microcrystalline silicon, and polycrystalline silicon.

According to one embodiment of the present disclosure, the photoelectric sensor comprises:

a first electrode formed between the transparent substrate and the hole transport layer; and

a second electrode formed on one side of the electron transport layer away from the light absorption layer.

According to one embodiment of the present disclosure, the first electrode is a single-layer structure or a multi-layer structure formed by at least one metal oxide material selected from indium zinc oxide, indium tin oxide, zinc oxide, and gallium zinc oxide.

According to one embodiment of the present disclosure, the second electrode is a single-layer structure or a multi-layer structure formed by at least one metal material of molybdenum, copper, aluminum, titanium, nickel, and cadmium.

According to one embodiment of the present disclosure, the photoelectric sensor comprises an insulation layer formed on the transparent substrate and covering the first electrode and the electron transport layer. The insulation layer is provided with a first via hole and a second via hole. The first via hole exposes the first electrode, and the second via hole exposes the electron transport layer.

The embodiments of the present disclosure further provide a method of manufacturing a photoelectric sensor. The method of manufacturing the photoelectric sensor comprises steps of:

forming a first electrode on a transparent substrate;

depositing a layer of molybdenum oxide on the transparent substrate and the first electrode;

sequentially depositing a light absorption material and an electron transport material on the molybdenum oxide; and

performing a patterning process on the electron transport material, the light absorption material, and the molybdenum oxide to form a hole transport layer, a light absorption layer, and an electron transport layer sequentially stacked and disposed on the first electrode.

According to one embodiment of the present disclosure, the method further comprises steps of:

forming an insulation layer on the transparent substrate, wherein the insulation layer covers the hole transport layer, the light absorption layer, and the electron transport layer;

etching the insulation layer to form a first via hole exposing the first electrode and a second via hole exposing the electron transport layer; and

forming a second electrode on the electron transport layer and the insulation layer.

According to one embodiment of the present disclosure, a forbidden band width of the molybdenum oxide is greater than or equal to 2.8 eV and less than or equal to 3.6 eV, and a work function of the molybdenum oxide is greater than or equal to 5.2 eV and less than or equal to 6.8 eV.

According to one embodiment of the present disclosure, the electron transport layer is an N-type semiconductor. The light absorption layer is an intrinsic semiconductor.

According to one embodiment of the present disclosure, a method of sequentially depositing the light absorption material and the electron transport material on the molybdenum oxide is a chemical vapor deposition method or an atomic layer deposition method.

The embodiments of the present disclosure further provide a display panel. The display panel comprises a photoelectric sensor and pixel units. The photoelectric sensor is disposed between and at least partially adjacent to the pixel units. The photoelectric sensor comprises:

a transparent substrate;

a hole transport layer disposed on the transparent substrate;

a light absorption layer disposed on one side of the hole transport layer away from the transparent substrate; and

an electron transport layer disposed on one side of the light absorption layer away from the hole transport layer;

wherein an out light side of each of the pixel units faces the transparent substrate, one side of the transparent substrate away from the hole transport layer is a light incident side of the photoelectric sensor, and a material of the hole transport layer is molybdenum oxide.

According to one embodiment of the present disclosure,

the display panel comprises:

a first electrode layer disposed on the transparent substrate, wherein the first electrode layer comprises a first electrode and a gate disposed at intervals in a same layer, and the hole transport layer is disposed on one side of the first electrode away from the transparent substrate;

a gate insulation layer disposed on the first electrode layer, wherein and the gate insulation layer exposes the first electrode;

an active layer disposed on the gate insulation layer, wherein the active layer comprises a non-doped region and two doped regions located on two sides of the non-doped region;

a source and a drain disposed on the active layer and respectively connected to corresponding one of the two doped regions;

an insulation layer formed on the electron transport layer, the source, and the drain, wherein the insulation layer exposes the electron transport layer and the drain; and

a second electrode formed on one side of the electron transport layer away from the light absorption layer, wherein the second electrode is connected to the drain.

According to one embodiment of the present disclosure, the gate, the active layer, the source, and the drain constitute a switching thin film transistor. The photoelectric sensor is connected to the switching thin film transistor.

According to one embodiment of the present disclosure, a forbidden band width of the molybdenum oxide is greater than or equal to 2.8 eV and less than or equal to 3.6 eV, and a work function of the molybdenum oxide is greater than or equal to 5.2 eV and less than or equal to 6.8 eV.

According to one embodiment of the present disclosure, the light absorption layer is an intrinsic semiconductor. The electron transport layer is an electronic semiconductor. The hole transport layer, the light absorption layer, and the electron transport layer form a semiconductor heterostructure.

According to one embodiment of the present disclosure, materials of the light absorption layer and the electron transport layer comprise any one of amorphous silicon, microcrystalline silicon, and polycrystalline silicon.

### Beneficial Effects:

The beneficial effects of the embodiments of the present disclosure: the embodiments of the present disclosure provide a photoelectric sensor, a method of manufacturing the same, and a display panel. The photoelectric sensor comprises a transparent substrate, a hole transport layer, a light absorption layer, and an electron transport layer. The hole transport layer is disposed on the transparent substrate. The light absorption layer is disposed on one side of the hole transport layer away from the transparent substrate. The electron transport layer is disposed on the light absorption layer away from the transparent substrate. One side of the transparent substrate away from the hole transport layer is a light incident side of the photoelectric sensor. A material of the hole transport layer is molybdenum oxide. The hole transport layer, the light absorption layer, and the electron transport layer constitute a semiconductor heterostructure. As such, disposing the hole transport layer on one side close to the transparent substrate and shielding the hole transport layer by use of the light absorption layer and the electron transport layer avoid the dissolution of molybdenum oxide in the hole transport layer during a cleaning process, thereby reducing the difficulty in the manufacturing process of the photoelectric sensor by use of molybdenum oxide as the hole transport layer material.

### BRIEF DESCRIPTION OF DRAWINGS

In order to explain the technical solutions of the present disclosure more clearly, the following will briefly introduce the drawings used in the description of the embodiments or the related art. Obviously, the drawings described below are only some embodiments of the present disclosure. For those skilled in the art, other drawings can be obtained based on these drawings without making creative efforts.

FIG. 1 is a schematic structural view of a photoelectric sensor provided by the embodiments of the present disclosure.

FIG. 2 is a flow chart of a method of manufacturing the photoelectric sensor provided by the embodiments of the present disclosure.

FIG. 3 is a flow chart of a method of manufacturing the photoelectric sensor provided by the embodiments of the present disclosure.

FIG. 4 is a plan view of a display panel provided by the embodiments of the present disclosure.

FIG. 5 is a schematic structural view of a display panel provided by the embodiments of the present disclosure.

### DETAILED DESCRIPTION OF PREFERRED EMBODIMENTS

The description of the following embodiments refers to the attached drawings to illustrate specific embodiments that the present disclosure can be implemented. Directional terms mentioned in the present disclosure, such as “top”, “bottom”, “front”, “rear”, “left”, “right”, “inside”, “outside”, “side”, etc., refer to the direction of the attached drawings only. Therefore, the directional terms used are to illustrate and understand the present disclosure, rather than to limit the present disclosure. In the figure, units with similar structures are indicated by the same reference numerals.

The disclosure will be further described below in combination with the drawings and specific embodiments:

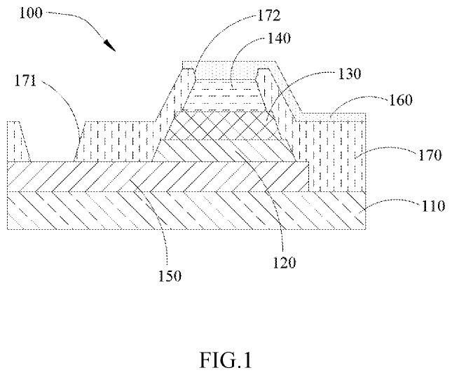

The embodiment of the present disclosure provides a photoelectric sensor, which will be described in detail below with reference to FIG. 1. As shown in FIG. 1, FIG. 1 is a schematic structural view of a photoelectric sensor provided by an embodiment of the present disclosure. The photoelectric sensor 100 comprises a transparent substrate 110, a hole transport layer 120, a light absorption layer 130, and an electron transport layer 140. The hole transport layer 120 is disposed on the transparent substrate 110. The light absorption layer 130 is disposed on one side of the hole transport layer 120 away from the transparent substrate 110. The electron transport layer 140 is disposed on one side of the light absorption layer 130 away from the hole transport layer 120.

In one embodiment of the present disclosure, a material of the transparent substrate 110 is glass. In practical applications, the material of the transparent substrate 110 is not limited to glass, but may also be a transparent material such as alumina, silicon, polyethylene naphthalate, polyethylene terephthalate, or polyimide, etc.

In one embodiment of the present disclosure, as shown in FIG. 1, the photoelectric sensor 100 is a photoelectric sensor with a bottom light-receiving structure. One side of the transparent substrate 110 away from the hole transport layer 120 is a light incident side of the photoelectric sensor 100. The ambient light irradiates the inside of the photoelectric sensor 100 through the side of the transparent substrate 110 away from the hole transport layer 120, passes through the hole transport layer 120, and is finally absorbed by the light absorption layer 130. The light absorption layer 130 generates photoacoustic carriers after absorbing light energy, and under the action of an applied reverse voltage, the electron-holes generated in the light absorption layer 130 accelerate and diffuse in opposite directions, and drift to the electron transport layer 140 and the hole transport layer 120, thereby generating a current proportional to the power of the ambient light and converting the optical signal of the ambient light into an electrical signal.

In the embodiment of the present disclosure, a material of the hole transport layer 120 is molybdenum oxide. Compared with a hole-type material used in the hole transport layer in the prior art, molybdenum oxide has a greater forbidden bandwidth and work function. The hole transport efficiency of the hole transport layer 120 is effectively enhanced, so that the photoelectric sensor 100 has a higher quantum efficiency. Moreover, molybdenum oxide may also reduce the additional absorption of light by the hole transport layer 120, thereby enhancing the sensitivity of the photoelectric sensor 100. Further, the required amount of the hole-type material may also be reduced, thereby reducing manufacturing costs.

In a practical manufacturing process, after disposing the hole transport layer 120 on one side close to the transparent substrate 110, molybdenum oxide, light absorption material, and hole transport material are sequentially deposited, and then a patterning process is performed on the hole transport material, light absorption material and molybdenum oxide to form the hole transport layer 120, the light absorption layer 130, and the electron transport layer 140 sequentially stacked. As such, the light absorption layer 130 and the electron transport layer 140 located on the hole transport layer 120 may be used to shield the hole transport layer 120. Therefore, the molybdenum oxide in the hole transport layer 120 is prevented from dissolving during a film cleaning process, thereby reducing the difficulty in the manufacturing process of the photoelectric sensor 100 using MoOx as the material of the hole transport layer 120.

Further, the forbidden bandwidth of the molybdenum oxide is greater than or equal to 2.8 eV and less than or equal to 3.6 eV, and the work function of the molybdenum oxide is greater than or equal to 5.2 eV and less than or equal to 6.8 eV.

In one embodiment of the present disclosure, the forbidden bandwidth of the molybdenum oxide is 3.2 eV, and the work function of the molybdenum oxide is 6 eV. As such, the molybdenum oxide may have a greater forbidden bandwidth and work function, thereby effectively enhancing the hole transport efficiency of the hole transport layer 120, allowing the photoelectric sensor 100 to have a higher quantum efficiency, thereby enhancing the sensitivity of the photoelectric sensor 100.

In practical applications, the forbidden bandwidth of the molybdenum oxide is not limited to 3.2 eV as mentioned above, but may also be 2.8 eV, 3 eV, 3.4 eV, or 3.6 eV, etc., and may only need to be between 2.8 eV and 3.6 eV. The work function of the molybdenum oxide is not limited to 6 eV as mentioned above, and may also be 5.2 eV, 5.6 eV, 6.4 eV, or 6.8 eV, etc., and may only need to be between 5.2 eV and 6.8 eV.

Further, the light absorption layer 130 is an intrinsic semiconductor. The electron transport layer 140 is an electronic semiconductor. The hole transport layer 120, the light absorption layer 130, and the electron transport layer 140 form a semiconductor heterostructure.

In one embodiment of the present disclosure, the photoelectric sensor 100 is a photoelectric sensor with a semiconductor heterostructure. The light absorption layer 130 is an intrinsic semiconductor. The electron transport layer 140 is an electronic semiconductor. The hole transport layer 120, the light absorption layer 130, and the electron transport layer 140 form a semiconductor heterostructure. Since the junction capacitance of the heterojunction itself in the semiconductor heterostructure is relatively great, it may be used as a storage capacitor in the circuit. Therefore, there is no need to provide a storage capacitor in the circuit of the photoelectric sensor, thereby effectively enhancing the identification rate of the photoelectric sensor.

Specifically, in one embodiment of the present disclosure, a material of the light absorption layer 130 is intrinsic non-doped silicon, and a form of silicon in the intrinsic non-doped silicon is amorphous silicon. In practical applications, the form of the intrinsic non-doped silicon is not limited to amorphous silicon, but may also be microcrystalline silicon or polycrystalline silicon.

Specifically, in one embodiment of the present disclosure, a material of the electron transport layer 140 is N-type heavily doped silicon, and a form of the silicon is the same as a form of the intrinsic non-doped silicon, and both are amorphous silicon. In practical applications, a form of silicon in the N-type heavily doped silicon is not limited to amorphous silicon as mentioned above, but may also be amorphous silicon or polycrystalline silicon, and the form of silicon in the N-type heavily doped silicon may be the same as or different from the form of silicon in the intrinsic non-doped silicon.

Further, as shown in FIG. 1, the photoelectric sensor 100 comprises a first electrode 150 and a second electrode 160. The first electrode 150 is disposed between the transparent substrate 110 and the hole transport layer 120. The second electrode 160 is disposed on one side of the electron transport layer 140 away from the light absorption layer 130. The first electrode 150 and the second electrode 160 are respectively connected to an external circuit and used to connect to an applied reverse voltage, so that the electrons and holes generated in the light absorption layer 130 accelerate and diffuse in opposite directions, and drift to the electron transport layer 140 and the hole transport layer 120, generating a current proportional to the power of the ambient light, thereby converting the optical signal of the ambient light into an electrical signal.

Specifically, the first electrode 150 is a transparent conductive electrode. A material of the first electrode 150 is indium tin oxide. As such, a light transmittance of the first electrode 150 may be enhanced, and an additional absorption of light by the first electrode 150 may be reduced, thereby further enhancing the sensitivity of the photoelectric sensor 100. In practical applications, the material of the first electrode 150 is not limited to indium tin oxide as mentioned above, but may also be any one material of indium zinc oxide, zinc oxide, and gallium zinc oxide, or may also be a multilayer structure formed by at least one metal oxide material of indium zinc oxide, indium tin oxide, zinc oxide, and gallium zinc oxide.

Specifically, the second electrode 160 is a metal conductive electrode. The second electrode 160 is a double-layer structure formed by sequentially stacking molybdenum and copper from bottom to top. In practical applications, a structure of the second electrode 160 is not limited to the double-layer metal structure mentioned above formed by sequentially stacking molybdenum and copper from bottom to top, but may also be a single-layer metal structure or a multiple-layer metal structure formed by one metal material such as molybdenum, copper, or aluminum; or may also be a two-layer metal structure or three-layer metal structure formed by sequentially stacking two or three materials, such as molybdenum/aluminum, molybdenum/titanium/aluminum, molybdenum/titanium/copper, nickel/copper, nickel/aluminum, aluminum/nickel, cadmium/copper, cadmium/aluminum, titanium/copper, and titanium/aluminum from bottom to top.

Further, as shown in FIG. 1, the photoelectric sensor 100 comprises an insulation layer 170. The insulation layer 170 is formed on the transparent substrate 110 and covers the first electrode 150 and the electron transport layer 140. The insulation layer 170 is provided with a first via hole 171 and a second via hole 172. The first via hole 171 exposes the first electrode 150, and the second via hole 172 exposes the electron transport layer 140. The first via hole 171 is used to expose the first electrode 150, so that the first electrode 150 may be connected to other circuits of the photoelectric sensor 100, and the second electrode 160 is connected to the electron transport layer 140 through the second via hole 172.

Specifically, the insulation layer 170 is a stacked structure formed by silicon nitride and silicon oxide. In practical applications, the insulation layer 170 may be a single-layer structure or a multi-layer structure formed by at least one material of aluminum oxide, silicon nitride, silicon dioxide, and aluminum nitride.

The photoelectric sensor 100 provided in one embodiment of the present disclosure may be applied to a variety of scenarios. Illustratively, the photoelectric sensor may be applied to sensors, such as a fingerprint identification sensor, a palmprint identification sensor, or a facial identification sensor.

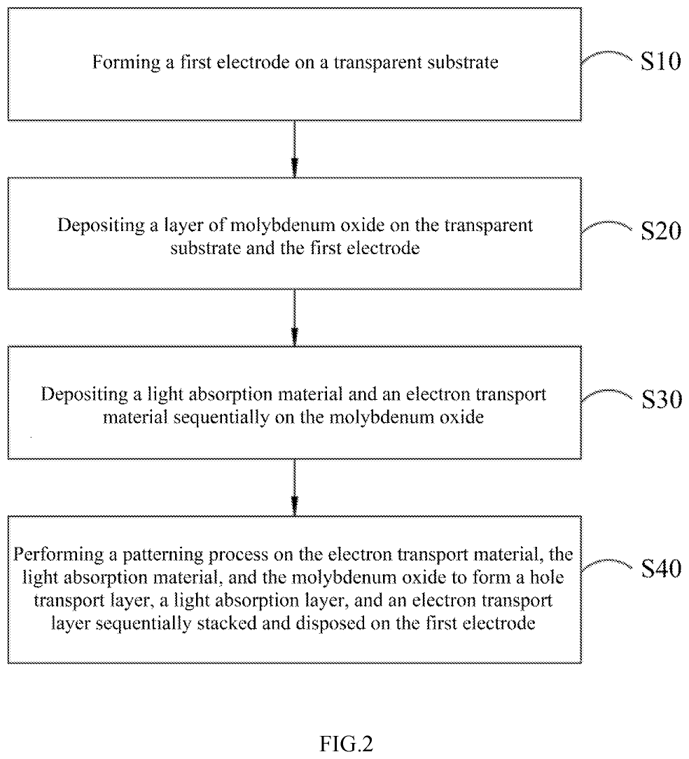

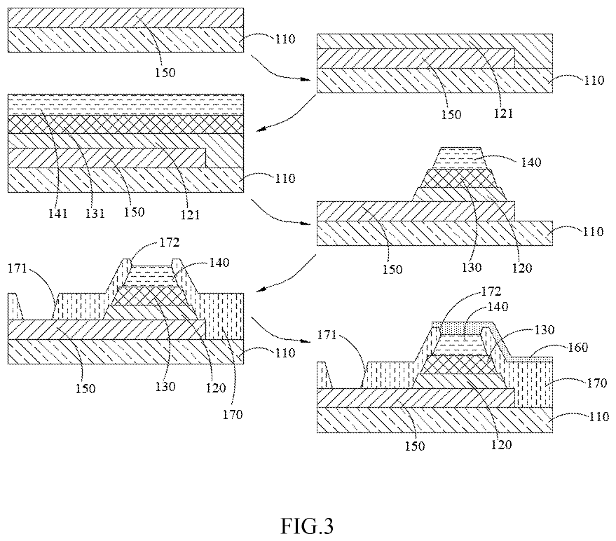

The embodiment of the present disclosure further provides a method of manufacturing a photoelectric sensor, which will be described in detail below with reference to FIG. 2 and FIG. 3. FIG. 2 is a flow chart of a method of manufacturing the photoelectric sensor provided by the embodiments of the present disclosure, and FIG. 3 is a flow chart of a method of manufacturing the photoelectric sensor provided by the embodiments of the present disclosure. The method of manufacturing the photoelectric sensor comprises steps of:

Step S10: forming a first electrode 150 on a transparent substrate 110.

Specifically, in the step S10, a material of the transparent substrate 110 is glass. In practical applications, the material of the transparent substrate 110 is not limited to glass, but may also be transparent material such as alumina, silicon, polyethylene naphthalate, polyethylene terephthalate, or polyimide, etc.

Specifically, in the step S10, it is necessary to deposit a layer of transparent electrode material on the transparent substrate 110, and then perform a patterning process on the layer of transparent electrode material to form a patterned first electrode 150. The transparent electrode material is indium tin oxide, which may enhance a light transmittance of the first electrode 150, reduce an additional absorption of light by the first electrode 150, and further enhance the sensitivity of the photoelectric sensor 100. In practical applications, the material of the first electrode 150 is not limited to indium tin oxide as mentioned above, but may also be any one material of indium zinc oxide, zinc oxide, and gallium zinc oxide, or may also be a multilayer structure formed by at least one metal oxide material of indium zinc oxide, indium tin oxide, zinc oxide, and gallium zinc oxide.

Step S20: depositing a layer of molybdenum oxide 121 on the transparent substrate 110 and the first electrode 150.

Specifically, in the step S20, a method of depositing a layer of molybdenum oxide 121 comprising sputtering, chemical vapor deposition (CVD), or evaporation. After the deposition is completed, the molybdenum oxide 121 needs to be annealed. An annealing process may be completed in an atmosphere of oxygen, nitrogen, argon or air. The duration and temperature required for the annealing process may be set according to the setting, which are not limited herein.

Step S30: depositing a light absorption material 131 and an electron transport material 141 sequentially on the molybdenum oxide 121.

Specifically, in the step S30, a method of depositing the light absorption material 131 and the electron transport material 141 is a chemical vapor deposition method. In practical applications, a method of depositing the light absorption material 131 and the electron transport material 141 is not limited to a chemical vapor deposition method, and an atomic layer deposition method or a plasma-enhanced chemical vapor deposition method may also be used.

Specifically, the light absorption material 131 is an intrinsic non-doped silicon, and a form of the intrinsic non-doped silicon is amorphous silicon. In practical applications, the form of intrinsic non-doped silicon may also be microcrystalline silicon or polycrystalline silicon.

Specifically, the electron transport material 141 is N-type heavily doped silicon, and a form of silicon in the N-type heavily doped silicon is amorphous silicon. In practical applications, the form of silicon in N-type heavily doped silicon may also be microcrystalline silicon or polycrystalline silicon.

Step S40: performing a patterning process on the electron transport material 141, the light absorption material 131, and the molybdenum oxide 121 to form a hole transport layer 120, a light absorption layer 130, and an electron transport layer 140 sequentially stacked and disposed on the first electrode 150.

It should be noted that in the step S40, the electron transport material 141, the light absorption material 131, and the molybdenum oxide 121 need to be patterned sequentially, and only one mask plate is needed to complete the patterning process of three layers mentioned above. After completing the patterning process on the electron transport material 141, the patterned electron transport layer 140 may be used as a mask plate, and then a patterning process on the lower layer, which is the light absorption material 131, is continuously performed.

Specifically, a method of patterning the electron transport material 141, the light absorption material 131, and the molybdenum oxide 121 is dry etching. In practical applications, a wet etching method may also be used to perform a patterning process on the electron transport material 141, the light absorption material 131, and the molybdenum oxide 121. As such, the light absorption layer 130 and the electron transport layer 140 located on the hole transport layer 120 may be used to shield the hole transport layer 120 to prevent the molybdenum oxide in the hole transport layer 120 from being dissolved during a film cleaning process, thereby reducing the difficulty in the manufacturing process of the photoelectric sensor 100 using MoOx as the material of the hole transport layer 120.

In one embodiment of the present disclosure, the light absorption layer 130 is an intrinsic semiconductor. The electron transport layer 140 is an electronic semiconductor. The hole transport layer 120, the light absorption layer 130, and the electron transport layer 140 constitute a semiconductor heterostructure. Since the junction capacitance of the heterojunction itself in the semiconductor heterostructure is relatively great, it may be used as a storage capacitor in the circuit. Therefore, there is no need to provide a storage capacitor in the circuit of the photoelectric sensor, thereby effectively enhancing the identification rate of the photoelectric sensor.

Further, the method further comprises steps of:

Step S50: forming an insulation layer 170 on the transparent substrate 110. The insulation layer 170 covers the hole transport layer 120, the light absorption layer 130, and the electron transport layer 140.

Specifically, the insulation layer 170 is a stacked structure formed by silicon nitride and silicon oxide. In practical applications, the insulation layer 170 may be a single-layer structure or a multi-layer structure formed by at least one material of aluminum oxide, silicon nitride, silicon dioxide, and aluminum nitride.

Step S60: etching the insulation layer 170 to form a first via hole 171 exposing the first electrode 150 and a second via hole 172 exposing the electron transport layer 140.

Specifically, in the step S60, the first via hole 171 exposes a part of the first electrode 150, which is used to subsequently connect the first electrode 150 to other circuits of the photoelectric sensor. The second via hole 172 exposes a part of the electron transport layer 140, which is used to allow the second electrode 160 formed subsequently to connect to the electron transport layer 140.

Step S70: forming a second electrode 160 on the electron transport layer 140 and the insulation layer 170.

Specifically, in the step S70, the second electrode 160 is a metal conductive electrode. The second electrode 160 is a double-layer structure formed by sequentially stacking molybdenum and copper from bottom to top. In practical applications, a structure of the second electrode 160 is not limited to the double-layer metal structure mentioned above formed by sequentially stacking molybdenum and copper from bottom to top, but may also be a single-layer metal structure or a multiple-layer metal structure formed by one metal material such as molybdenum, copper, or aluminum; or may also be a two-layer metal structure or three-layer metal structure formed by sequentially stacking two or three materials such as molybdenum/aluminum, molybdenum/titanium/aluminum, molybdenum/titanium/copper, nickel/copper, nickel/aluminum, aluminum/nickel, cadmium/copper, cadmium/aluminum, titanium/copper, and titanium/aluminum from bottom to top.

Further, the forbidden bandwidth of the molybdenum oxide 121 is greater than or equal to 2.8 eV and less than or equal to 3.6 eV, and the work function of the molybdenum oxide is greater than or equal to 5.2 eV and less than or equal to 6.8 eV.

In one embodiment of the present disclosure, the forbidden bandwidth of the molybdenum oxide 121 is 3.2 eV, and the work function of the molybdenum oxide is 6 eV. As such, the molybdenum oxide may have a greater forbidden bandwidth and work function, thereby effectively enhancing the hole transport efficiency of the hole transport layer 120, allowing the photoelectric sensor 100 to have a higher quantum efficiency, thereby enhancing the sensitivity of the photoelectric sensor 100.

In practical applications, the forbidden bandwidth of the molybdenum oxide 121 is not limited to 3.2 eV as mentioned above, but may also be 2.8 eV, 3 eV, 3.4 eV, or 3.6 eV, etc., and may only need to be between 2.8 eV and 3.6 eV. The work function of the molybdenum oxide is not limited to 6 eV as mentioned above, and may also be 5.2 eV, 5.6 eV, 6.4 eV, or 6.8 eV, etc., and may only need to be between 5.2 eV and 6.8 eV.

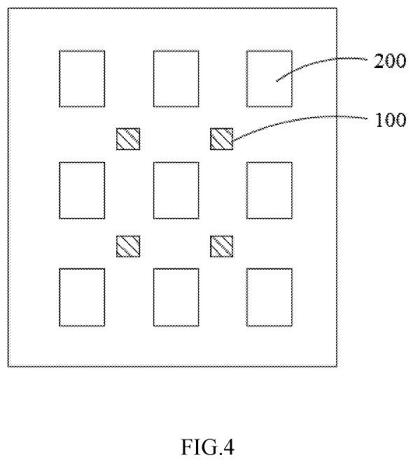

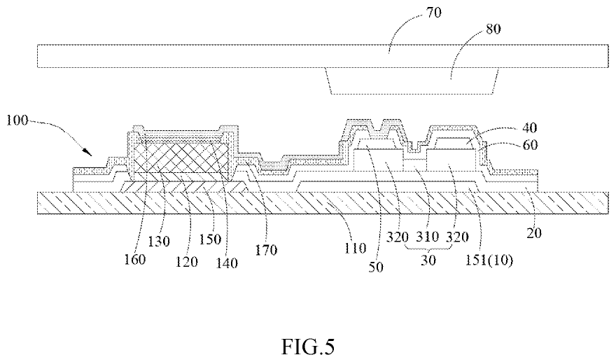

One embodiment of the present disclosure further provides a display panel, which will be described in detail below with reference to FIG. 4 and FIG. 5. FIG. 4 is a plan view of the display panel provided by the embodiments of the present disclosure, and FIG. 5 is a schematic structural view of the display panel provided by the embodiments of the present disclosure. The display panel comprises the photoelectric sensor 100 provided by the above-mentioned embodiments and pixel units 200. The photoelectric sensor 100 is disposed between and at least partially adjacent to the pixel units 200. Such method may not affect the pixel arrangement and the display effect of the pixel units 200.

The photoelectric sensor 100 comprises a transparent substrate 110, a hole transport layer 120, a light absorption layer 130, and an electron transport layer 140. The hole transport layer 120 is disposed on the transparent substrate 110. The light absorption layer 130 is disposed on one side of the hole transport layer 120 away from the transparent substrate 110. The electron transport layer 140 is disposed on the side of the light absorption layer 130 away from the hole transport layer 120.

In one embodiment of the present disclosure, the display panel is an organic light-emitting diode display panel with a bottom light-emitting structure. The pixel units 200 are formed on the transparent substrate 110. An out light side of each of the pixel units 200 faces the transparent substrate 110. One side of the transparent substrate 110 away from the hole transport layer 120 is a light incident side of the photoelectric sensor 100.

In one embodiment of the present disclosure, a material of the hole transport layer 120 is molybdenum oxide. Compared with a hole-type material used in the hole transport layer in the prior art, molybdenum oxide has a greater forbidden bandwidth and work function. The hole transport efficiency of the hole transport layer 120 may be effectively enhanced, so that the photoelectric sensor 100 has a higher quantum efficiency. Moreover, molybdenum oxide may also reduce the additional absorption of light by the hole transport layer 120, thereby enhancing the sensitivity of the photoelectric sensor 100. Further, the required amount of hole-type material may also be reduced, thereby reducing manufacturing costs.

Further, the display panel comprises a first electrode layer 10, a gate insulation layer 20, an active layer 30, a source 40, a drain 50, an interlayer dielectric layer 60, an insulation layer 170, and a second electrode 160. The first electrode layer 10 is disposed on the transparent substrate 110. The first electrode layer 10 comprises a first electrode 150 and a gate 151 disposed at intervals in a same layer. The hole transport layer 120 is disposed on one side the first electrode 150 away from the transparent substrate 110. The gate insulation layer 20 is formed on the first electrode layer 10, and the gate insulation layer 20 exposes the first electrode 150. The active layer 30 is disposed on the gate insulation layer 20 and the active layer 30 comprises a non-doped region 310 and two doped regions 320 located on two sides of the non-doped region 310. The source 40 and the drain 50 are disposed on the active layer 30 and are respectively connected to corresponding one of the two doped regions 320 located on two sides of the non-doped regions 310.

The interlayer dielectric layer 60 covers the source 40, the drain 50, and the gate insulation layer 20. The insulation layer 170 is formed on the interlayer dielectric layer 60, the electron transport layer 140, the source 40, and the drain 50, and the electron transport layer 140 and the drain 50 are exposed. The second electrode 160 is disposed on one side of the electron transport layer 140 away from the light absorption layer 130, and connected to the drain 50.

Further, the gate 151, the active layer 30, the source 40, and the drain 50 constitute a switching thin film transistor. The switching thin film transistor is connected to the photoelectric sensor 100.

The display panel further comprises a cover plate 70. A black matrix 80 is provided on the side of the cover plate 70 facing the transparent substrate 110, and the switching thin film transistor is disposed opposite the black matrix 80. The photoelectric sensor 100 is disposed outside the coverage area of the black matrix 80.

The transparent substrate 110 further comprises a scan line and a signal line not shown in the figures. The photosensitive element is electrically connected to the switching thin film transistor. The gate 151 of the switching thin film transistor is electrically connected to the scan line. The source 40 of the switching thin film transistor is electrically connected to the signal line. The drain of the switching thin film transistor is electrically connected to the second electrode 160 of the photoelectric sensor 100. The signal line is used to read the photocurrent signal output by the photoelectric sensor 100, so as to achieve the photoelectric sensing function of the photoelectric sensor 100.

In the display panel provided by the embodiment of the present disclosure, the photoelectric sensor 100 may be applied to various scenarios. For example, the photoelectric sensor may be applied to sensors, such as a fingerprint identification sensor, a palmprint identification sensor, or a facial identification sensor.

In summary, the embodiments of the present disclosure provide a photoelectric sensor, a method of manufacturing the same, and a display panel. The photoelectric sensor comprises a transparent substrate, a hole transport layer, a light absorption layer, and an electron transport layer. The hole transport layer is disposed on the transparent substrate. The light absorption layer is disposed on one side of the hole transport layer away from the transparent substrate. The electron transport layer is disposed on one side of the light absorption layer away from the hole transport. One side of the transparent substrate away from the hole transport layer is a light incident side of the photoelectric sensor. A material of the hole transport layer is molybdenum oxide. The hole transport layer, the light absorption layer, and the electron transport layer constitute a semiconductor heterostructure. As such, disposing the hole transport layer on one side close to the transparent substrate and shielding the hole transport layer by use of the light absorption layer and the electron transport layer avoid the dissolution of molybdenum oxide in the hole transport layer during a cleaning process, thereby reducing the difficulty in manufacturing process of the photoelectric sensor by use of molybdenum oxide as the hole transport layer material.

In summary, although the preferred embodiments of the present disclosure are disclosed as above, the preferred embodiments mentioned above are not intended to limit the present disclosure. Those of ordinarily skilled in the art can make various changes and modification without departing from the spirit and scope of the present disclosure. Therefore, the claimed scope of the present disclosure is based on the scope defined by the claims.

What is claimed is:

1. A photoelectric sensor, comprising:
a transparent substrate;
a hole transport layer disposed on the transparent substrate;
a light absorption layer disposed on one side of the hole transport layer away from the transparent substrate; and
an electron transport layer disposed on one side of the light absorption layer away from the hole transport layer;
wherein one side of the transparent substrate away from the hole transport layer is a light incident side of the photoelectric sensor, and a material of the hole transport layer is molybdenum oxide.

2. The photoelectric sensor according to claim 1, wherein a forbidden band width of the molybdenum oxide is greater than or equal to 2.8 eV and less than or equal to 3.6 eV, and a work function of the molybdenum oxide is greater than or equal to 5.2 eV and less than or equal to 6.8 eV.

3. The photoelectric sensor according to claim 1, wherein the light absorption layer is an intrinsic semiconductor, the electron transport layer is an electronic semiconductor, and the hole transport layer, the light absorption layer, and the electron transport layer form a semiconductor heterostructure.

4. The photoelectric sensor according to claim 3, wherein materials of the light absorption layer and the electron transport layer comprise any one of amorphous silicon, microcrystalline silicon, and polycrystalline silicon.

5. The photoelectric sensor according to claim 1, wherein the photoelectric sensor comprises:
a first electrode disposed between the transparent substrate and the hole transport layer; and
a second electrode disposed on one side of the electron transport layer away from the light absorption layer.

6. The photoelectric sensor according to claim 5, wherein the first electrode is a single-layer structure or a multi-layer structure formed by at least one metal oxide material selected from indium zinc oxide, indium tin oxide, zinc oxide, and gallium zinc oxide.

7. The photoelectric sensor according to claim 5, wherein the second electrode is a single-layer structure or a multi-layer structure formed by at least one metal material of molybdenum, copper, aluminum, titanium, nickel, and cadmium.

8. The photoelectric sensor according to claim 5, wherein the photoelectric sensor comprises an insulation layer disposed on the transparent substrate and covering the first electrode and the electron transport layer, and wherein the insulation layer is provided with a first via hole and a second via hole, the first via hole exposes the first electrode, and the second via hole exposes the electron transport layer.

9. A method of manufacturing a photoelectric sensor, comprising steps of:
forming a first electrode on a transparent substrate;
depositing a layer of molybdenum oxide on the transparent substrate and the first electrode;
sequentially depositing a light absorption material and an electron transport material on the molybdenum oxide; and
performing a patterning process on the electron transport material, the light absorption material, and the molybdenum oxide to form a hole transport layer, a light absorption layer, and an electron transport layer sequentially stacked and disposed on the first electrode.

10. The method of manufacturing the photoelectric sensor according to claim 9, wherein the method further comprises steps of:
forming an insulation layer on the transparent substrate, wherein the insulation layer covers the hole transport layer, the light absorption layer, and the electron transport layer;
etching the insulation layer to form a first via hole exposing the first electrode and a second via hole exposing the electron transport layer; and
forming a second electrode on the electron transport layer and the insulation layer.

11. The method of manufacturing the photoelectric sensor according to claim 9, wherein a forbidden band width of the molybdenum oxide is greater than or equal to 2.8 eV and less than or equal to 3.6 eV, and a work function of the molybdenum oxide is greater than or equal to 5.2 eV and less than or equal to 6.8 eV.

12. The method of manufacturing the photoelectric sensor according to claim 9, wherein the electron transport layer is an N-type semiconductor, the light absorption layer is an intrinsic semiconductor, and the hole transport layer, the light absorption layer, and the electron transport layer form a semiconductor heterostructure.

13. The method of manufacturing the photoelectric sensor according to claim 9, wherein a method of sequentially depositing the light absorption material and the electron transport material on the molybdenum oxide is a chemical vapor deposition method or an atomic layer deposition method.

14. A display panel, comprising a photoelectric sensor and pixel units, wherein the photoelectric sensor is disposed between and at least partially adjacent to the pixel units, and the photoelectric sensor comprises:
a transparent substrate;
a hole transport layer disposed on the transparent substrate;
a light absorption layer disposed on one side of the hole transport layer away from the transparent substrate; and
an electron transport layer disposed on one side of the light absorption layer away from the hole transport layer;
wherein an out light side of each of the pixel units faces the transparent substrate, one side of the transparent substrate away from the hole transport layer is a light incident side of the photoelectric sensor, and a material of the hole transport layer is molybdenum oxide.

15. The display panel according to claim 14, wherein the display panel comprises:
a first electrode layer disposed on the transparent substrate, wherein the first electrode layer comprises a first electrode and a gate disposed at intervals in a same layer, and the hole transport layer is disposed on one side of the first electrode away from the transparent substrate;
a gate insulation layer disposed on the first electrode layer, wherein and the gate insulation layer exposes the first electrode;
an active layer disposed on the gate insulation layer, wherein the active layer comprises a non-doped region and two doped regions located on two sides of the non-doped region;
a source and a drain disposed on the active layer and respectively connected to corresponding one of the two doped regions;
an insulation layer disposed on the electron transport layer, the source, and the drain, wherein the insulation layer exposes the electron transport layer and the drain; and
a second electrode disposed on one side of the electron transport layer away from the light absorption layer, wherein the second electrode is connected to the drain.

16. The display panel according to claim 15, wherein the gate, the active layer, the source, and the drain constitute a switching thin film transistor, and the photoelectric sensor is connected to the switching thin film transistor.

17. The display panel according to claim 14, wherein a forbidden band width of the molybdenum oxide is greater than or equal to 2.8 eV and less than or equal to 3.6 eV, and a work function of the molybdenum oxide is greater than or equal to 5.2 eV and less than or equal to 6.8 eV.

18. The display panel according to claim 14, wherein the light absorption layer is an intrinsic semiconductor, the electron transport layer is an electronic semiconductor, and the hole transport layer, the light absorption layer, and the electron transport layer form a semiconductor heterostructure.

19. The display panel according to claim 14, wherein materials of the light absorption layer and the electron transport layer comprise any one of amorphous silicon, microcrystalline silicon, and polycrystalline silicon.
